(19) United States
(12) Patent Application Publication
(10) Pub. No.: US 2012/0002469 A1
(43) Pub. Date: Jan. 5, 2012

(54) NONVOLATILE SEMICONDUCTOR MEMORY DEVICE

(75) Inventors: Akihiro IMAMOTO, Yokohama-shi (JP); Naofumi Abiko, Yokohama-shi (JP)

(73) Assignee: Kabushiki Kaisha Toshiba, Tokyo (JP)

(21) Appl. No.: 13/051,638

(22) Filed: Mar. 18, 2011

(30) Foreign Application Priority Data
Jul. 2, 2010 (JP) 2010-151921

(51) Int. Cl. G11C 16/04

(52) U.S. Cl. 365/185.03

(57) ABSTRACT

A nonvolatile semiconductor memory device according to an embodiment includes: a memory cell array including a plurality of memory cells selected by word lines and bit lines, each memory cell being capable of storing N-bit data, a set of n-th bits of a plurality of memory cells selected by one of the word lines constituting an n-th physical page, and a predetermined number of the bit lines constituting one column; and a data writing unit that divides each of first to N-th input data of the length of the physical page or less input from the outside into unit data of the length of the column, changes at least a portion of the order of unit data of the first to N-th input data of a predetermined column in the predetermined column before data writing, and performs writing.

### CROSS-REFERENCE TO RELATED APPLICATIONS

This application is based upon and claims the benefit of priority from the prior Japanese Patent Application No. 2010-151921, filed on Jul. 2, 2010, the entire contents of which are incorporated herein by reference.

### FIELD

Embodiments described herein relate generally to a nonvolatile semiconductor memory device.

### BACKGROUND

In recent development of nonvolatile semiconductor memory devices, in order to achieve large capacity, multi-level technology of storing a plurality of bits of information in one memory cell has been normally used. However, in the case of using the multi-level technology, a difference between threshold distributions used for representing data is small, and thus a write error during data writing, a read error during data reading and the like, easily occur.

For this reason, in the related art, as one of nonvolatile semiconductor memory devices for solving the above problems, a NAND-type flash memory with an error correcting code (ECC) system mounted has been proposed. However, in error correction based on an ECC of the flash memory, the following problem occurs during data reading. For example, in the case of a flash memory using memory cells each of which stores 3 bits, there are 3 kinds of physical pages, i.e., an upper (U) page, a middle (M) page, and a lower (L) page, and the number of times data is read varies according to the kinds of physical pages. As a result, a rate of occurrence of errors also varies according to the kinds of physical pages. In this case, in one physical page having one ECC frame stored therein without changing the format of the ECC frame, a variation in the error correction efficiency occurs according to the kind of storing physical page, and thus the error correction efficiency of the entire device is not improved.

### BRIEF DESCRIPTION OF THE DRAWINGS

FIG. 1 is a block diagram illustrating a nonvolatile semiconductor memory device according to a first embodiment;

FIG. 2 is a diagram illustrating a configuration of a memory cell array of the nonvolatile semiconductor memory device;

FIG. 3 is a block diagram illustrating a sense amplifier and data latch unit of the nonvolatile semiconductor memory device;

FIG. 4 is a diagram illustrating a relationship between threshold distributions and a bit assignment pattern of the nonvolatile semiconductor memory device;

FIG. 5 is a diagram illustrating unit data retained in data latches of the nonvolatile semiconductor memory device before and after data transmission between the data latches;

FIG. 6A is a flowchart illustrating a procedure of converting input data to storage data in the nonvolatile semiconductor memory device;

FIG. 6B is a flowchart illustrating a procedure of converting the input data to the storage data in the nonvolatile semiconductor memory device;

FIG. 6C is a flowchart illustrating a procedure of converting the input data to the storage data in the nonvolatile semiconductor memory device;

FIG. 7 is a diagram illustrating a pattern of data retained in the data latches after input data is transmitted in the case where each memory cell stores two bits in the nonvolatile semiconductor memory device;

FIG. 8 is a diagram illustrating a pattern of data retained in the data latches after input data is transmitted in the case where each memory cell stores three bits in the nonvolatile semiconductor memory device;

FIG. 9 is a diagram illustrating a pattern of data retained in the data latches after input data is transmitted in the case where each memory cell stores four bits in the nonvolatile semiconductor memory device;

FIG. 10 is a diagram illustrating unit data retained in data latches of a nonvolatile semiconductor memory device according to a second embodiment before and after data transmission between the data latches;

FIG. 11 is a diagram illustrating unit data retained in data latches of a nonvolatile semiconductor memory device according to a third embodiment before and after data transmission between the data latches; and

FIG. 12 is a diagram illustrating unit data retained in data latches of nonvolatile semiconductor memory devices according to comparative examples before and after data transmission between the data latches.

### DETAILED DESCRIPTION

A nonvolatile semiconductor memory device according to an embodiment includes: a memory cell array including a plurality of word lines, a plurality of bit lines intersecting with the plurality of word lines, and a plurality of memory cells selected by the word lines and the bit lines, each memory cell being capable of storing N-bit (N is an integer of 2 or more) data, a set of n-th bits (n is an integer of 1 to N) of a plurality of memory cells selected by one of the word lines constituting an n-th physical page, and a predetermined number of the bit lines constituting one column; and a data writing unit that divides each of first to N-th input data of the length of the physical page or less input from the outside into unit data of the length of the column, changes at least a portion of the order of unit data of the first to N-th input data of a predetermined column in the predetermined column before data writing, and performs writing.

Hereinafter, nonvolatile semiconductor memory devices according to embodiments will be described with reference to the drawings.

### First Embodiment

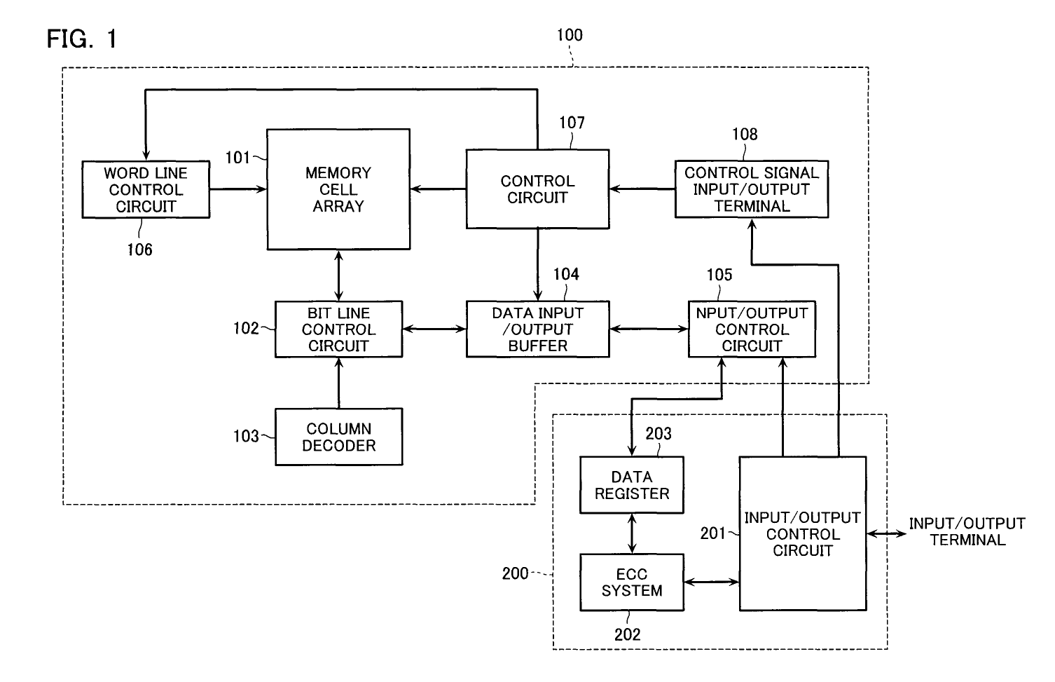

FIG. 1 is a diagram illustrating a memory system including a nonvolatile semiconductor memory device (hereinafter, referred to as a “semiconductor memory device”) according to a first embodiment. Here, a NAND flash memory will be described as an example of the semiconductor memory device.

The memory system according to the first embodiment includes a semiconductor memory device 100 and a controller 200 controlling the semiconductor memory device 100.

The semiconductor memory device 100 includes a memory cell array 101. The memory cell array 101 includes a plurality of bit lines, a plurality of word lines, a common source line, and a plurality of memory cells which are electrically rewritable and are arranged in a matrix. In the memory cells, not only multi-value data which are information bits but also redundant data for error correction on the information bits are stored.

The memory cell array 101 is connected to a word line control circuit 106 for controlling word line voltages.

The word line control circuit 106 supplies voltages necessary for a data reading operation or a verifying operation of a data writing operation, such as a voltage of a lower limit of a plurality of (8 in the case where each memory cell stores 3 bits) threshold distributions stored in the memory or a voltage between neighboring threshold distributions, to the word lines.

Also, the memory cell array 101 is connected to a bit line control circuit 102 for controlling the bit lines, and to a column decoder 103 through the bit line control circuit 102. The bit line control circuit 102 is a portion of a data writing unit.

The column decoder 103 performs bit line selection based on address information given from the controller 200.

The bit line control circuit 102 has not only a function of reading storage data of the memory cells of the memory cell array 101 through the bit lines but also a data latch function of retaining read data or write data. Further, the bit line control circuit 102 supplies voltages necessary for writing data to the memory cells of the memory cell array 101 through the bit lines.

The bit line control circuit 102 is connected to a data input/output buffer 104, and to an input/output control circuit 105 through the data input/output buffer 104. The input/output control circuit 105 controls data input and output of the semiconductor memory device 100. Write data transmitted from the controller 200 is transmitted to the data input/output buffer 104 by the input/output control circuit 105 and is stored in the data input/output buffer 104. Meanwhile, read data transmitted from the memory cell array 101 is stored in the data input/output buffer 104 through the bit line control circuit 102 and then transmitted to the controller by the input/output control circuit 105.

Further, the semiconductor memory device 100 includes a control circuit 107 controlling the bit line control circuit 102, the column decoder 103, the data input/output buffer 104, and the word line control circuit 106.

The control circuit 107 receives a control signal transmitted from the controller 200 through a control signal input/output terminal 108.

The controller 200 includes an input/output control circuit 201 controlling data communication with the outside, an ECC system 202 generating redundant data from input data or performing error correction on read data, and a data register 203 for retaining data handled in the ECC system. Input data given from the outside is transmitted as information data to the input/output control circuit 105 of the semiconductor memory device 100 by the input/output control circuit 201 and is also transmitted to the ECC system 202 in order to generate the redundant data for error correction. Meanwhile, read data from the semiconductor memory device 100 is transmitted to the ECC system 202 through the data register 203, subjected to error correction in the ECC system 202, then transmitted to the input/output control circuit 201, and output as output data from an input/output terminal.

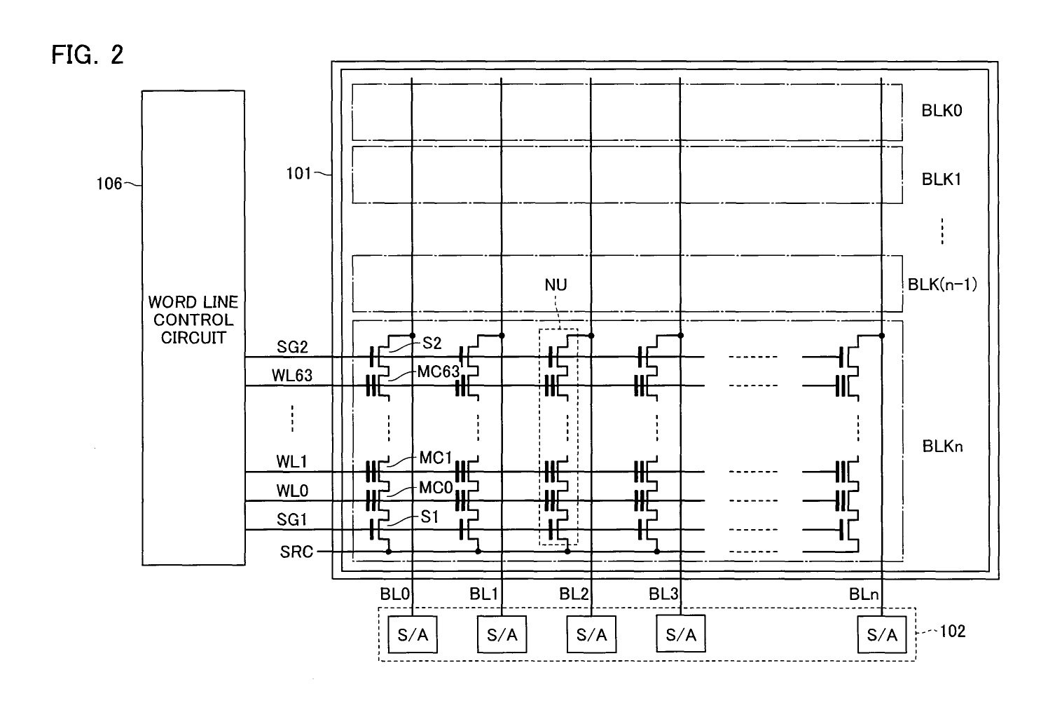

Next, a configuration of the memory cell array 101 illustrated in FIG. 1 will be described with reference to FIG. 2.

As illustrated in FIG. 2, the memory cell array 101 is configured by arranging NAND cell units (NAND strings) NU.

Each NAND cell unit NU includes a plurality of (64 in the example of FIG. 2) memory cells MC0 to MC63 connected in series. One end of each NAND cell unit NU is connected to a cell source line SRC through a selection gate transistor S1, and the other end thereof is connected to a bit line BL through a selection gate transistor S2.

Control gates of the memory cells MC0 to MC63 are connected to different word lines WL0 to WL63, respectively, and gates of the selection gate transistors S1 and S2 are connected to selection gate lines SG1 and SG2, respectively.

At one end of each bit line BL, a sense amplifier and data latch unit which is a portion of the bit line control circuit 102 is disposed. A set of memory cells MC selected by one word line WL constitutes a “page” which is a data access unit during simultaneous writing or reading.

Moreover, in the following description, the “page” may be defined not only as the data access unit and but also as a hierarchy of storage data in the case where each memory cell MC stores multi-value data, that is, a program stage. In this case, the “page” may be called a “physical page”, or a lower (L) page, a middle (M) page, an upper (U) page, or the like. Also, the “page” may be defined as an ECC frame of a predetermined size including information data input from the outside. In this case, the “page” may be called a “physical page”, or a first page, a second page, a third page, or the like.

A set of the NAND cell units NU arranged in the direction of the word lines WL constitutes a block which is a basic unit of data erasing. The memory cell array 101 includes a plurality of blocks BLK (BLK0, BLK1, . . . , and BLKn) arranged in the direction of the bit lines BL.

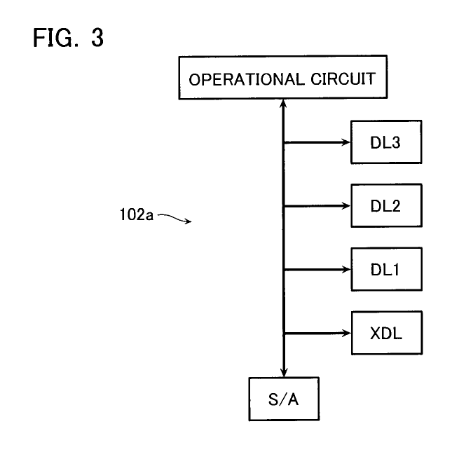

Next, a configuration of the sense amplifier and data latch unit of the semiconductor memory device will be described with reference to FIG. 3.

A sense amplifier and data latch unit 102a includes a sense amplifier S/A provided at one end of a bit line BL of the memory cell array 101, an operational circuit performing data transmission between the memory cell array 101 and the data input/output buffer 104 and an operation necessary during the data transmission, and data latches DL1, DL2, DL3, and XDL serving as data retaining units. Here, each of the data latches DL1, DL2, DL3, and XDL includes a bit latch circuit corresponding to one column, for example, 8-bit (1-byte) data.

Next, a relationship between threshold distributions and data assignment of the memory cells MC will be described.

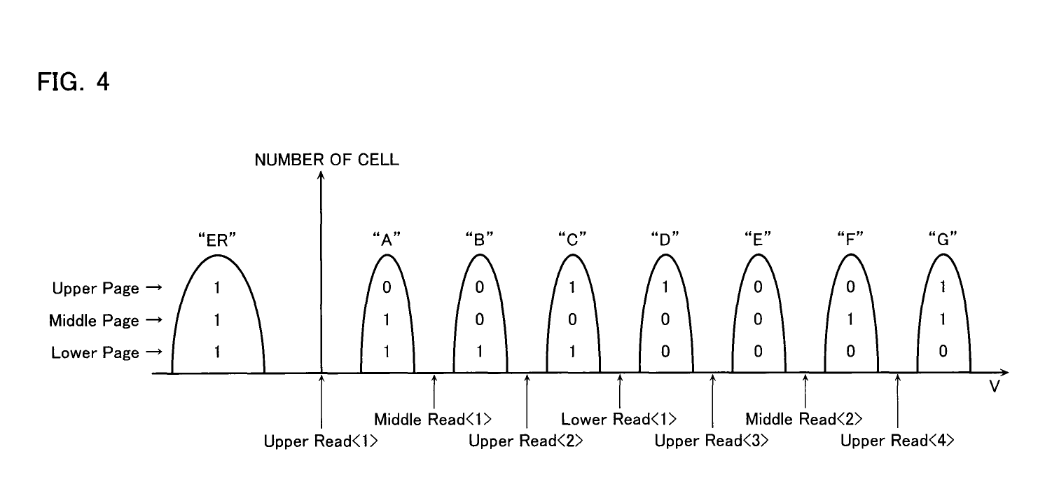

FIG. 4 is a diagram illustrating a relationship between threshold distributions and bit assignment in the case where 8 values (3 bits) are stored in memory cells of the semiconductor memory device.

As illustrated in FIG. 4, the threshold distributions are divided into 8 threshold levels from an ER level at which the threshold voltage is lowest to a G level at which the threshold voltage is highest. The ER level, an A level, a B level, a C level, a D level, an E level, an F level, and the G level correspond to binary data “111”, “011”, “001”, “101”, “100”, “000”, “010” and “110”, respectively. Here, the uppermost bit to the lowermost bit of 3-bit data retained in the memory cell MC correspond to bits constituting the upper (U) page, the middle (M) page, and the lower (L) page, respectively.

Next, data reading from the memory cell MC will be described.

In order to read data, in advance, the selection gate transistors S1 are turned on and the bit lines are precharged with a power supply voltage or the like. In this state, a read pass voltage higher than the upper limit of the threshold distribution of the G level is supplied to non-selected word lines, and any read voltage between neighboring threshold distributions is supplied to a selected word line. Further, the selection gate transistor S2 is turned on. In this case, non-selected memory cells whose control gates are supplied with the read pass voltage function as pass gates regardless of the threshold levels thereof. As a result, in the case where a selected memory cell is in an ON state, the bit line and the cell source line are electrically connected to each other such that the level of the bit line drops to the level of the cell source line. On the other hand, in the case where the selected memory cell is in an OFF state, the level of the bit line does not change. A change in the bit line is detected and amplified by the sense amplifier, whereby the threshold level of the memory cell is determined.

For example, in the case where the level of the bit line BL does not change when a read voltage between the A level and the B level is applied to the selected word line WL, and the level of the bit line BL is lowered when a read voltage between the B level and the C level is applied, it can be found that threshold level of the selected memory cell is the B level. In the cases of performing a read operation on any physical page of the U page, the M page, and the L page, the same principle of the data read operation is applicable but the number of read times varies.

Referring to the bit assignment illustrated in FIG. 4, in the case of the L page, “1” and “0” are assigned to the ER level to the C level and the D level to the G level, respectively. Therefore, it is possible to determine data of the L page only by single data reading based on a read voltage between the C level and the D level (Lower Read<1>). In contrast, in the case of the M page, “1” is assigned to the ER level and the A level, “0” is assigned to the B level to the E level, and “1” is assigned to the F level and the G level. Therefore, in order to determine data of the M page, it is necessary to perform read operations twice based on two read voltages, that is, a read voltage between the A level and the B level (Middle Read<1>) and a read voltage between the E level and the F level (Middle Read<2>). Further, in the case of the U page, “1” is assigned to the EL level, “0” is assigned to the A level and the B level, “1” is assigned to the C level and the D level, “0” is assigned to the E level and the F level, and “1” is assigned to the G level. Therefore, in order to determine data of the U page, it is necessary to perform reading based on each of four read voltages, that is, a read voltage between the ER level and the A level (Upper Read<1>), a read voltage between the B level and the C level (Upper Read<2>), a read voltage between the D level and the E level (Upper Read<3>), and a read voltage between the F level and the G level (Upper Read<4>).

Next, based on the fact that the number of read times is different for each of the physical pages, error correction based on ECC is considered.

It is assumed that an ECC frame with added redundant data for error correction on information data of one page input from the outside is generated and one ECC frame is stored in one physical page. Here, for example, if ECC frames of a first page, a second page, and a third page are generated from consecutive 3-bit information data, the first page, the second page, and the third page are written in the L page, the M page, and the U page, respectively. However, as described above, in the data reading operations from the L page, the M page, and the U page, the number of read times is different. For this reason, in the reading from the U page in which the number of read times is largest, naturally, error easily occurs and error correction efficiency based on the ECC is low. In contrast, in the reading from the L page in which the number of read times is smallest, error is less likely to occur and the error correction efficiency based on the ECC is high. In this case, if the entire memory system is considered, the error correction efficiency based on the ECC is bad.

For this reason, in the semiconductor memory device according to this embodiment, the first page, the second page, and the third page are not stored in the U page, the M page, and the L page as they are. Data (hereinafter, referred to as “unit data”) of a length of a column constituting each of the first page, the second page, and the third page is replaced with unit data of another logical page in the same column, and is stored in a physical page. In this way, one logical page is distributed to the L page, the M page, and the U page, thereby capable of averaging the rates of error occurrence of the first page, the second page, and the third page.

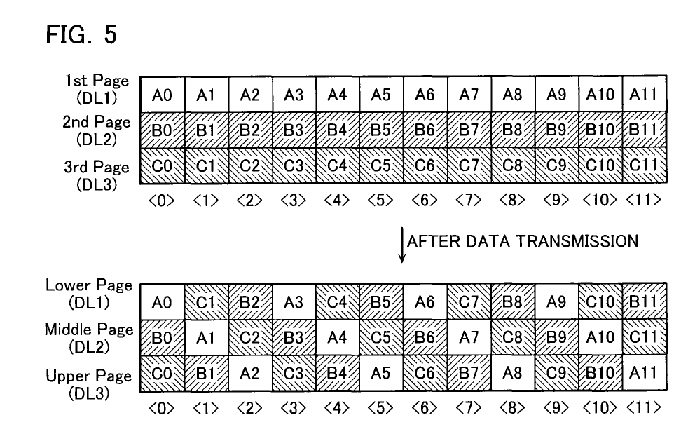

FIG. 5 illustrates a specific example thereof and is a diagram illustrating a relationship between logical pages and physical pages. Here, it is assumed that the first page includes unit data A0 to A11, the second page includes unit data B0 to B11, and the third page includes unit data C0 to C11.

First, the data of the first page, the data of the second page, and the data of the third page transmitted from the controller 200 are retained as they are in the data latches DL1, DL2, and DL3 of the sense amplifier and data latch unit 102a, respectively. The states of the data latches DL1, DL2, and DL3 at this time are as illustrated on the upper portion of FIG. 5.

Then, the data of the logical pages are sorted by the operational circuit of the sense amplifier and data latch unit 102a as illustrated in the lower portion of FIG. 5 and is written in the physical pages in the memory cell array 101. Specifically, in the data latches DL1, DL2, and DL3 of a column <0>, the unit data A0, B0, and C0 of the first page, the second page, and the third page are retained, respectively. In the data latches DL1, DL2, and DL3 of a column <1>, the unit data C1, A1, and B1 of the third page, the first page, and the second page are retained, respectively. In the data latches DL1, DL2, and DL3 of a column <2>, the unit data B2, C2, and A2 of the second page, the third page, and the first page are retained, respectively. Sequentially, similarly to the columns <0> to <2>, replacement (transmission) of the unit data between the data latches DL is performed.

Finally, the data retained in the data latches DL1, DL2, and DL3 are written in the L page, the M page, and the U page, respectively.

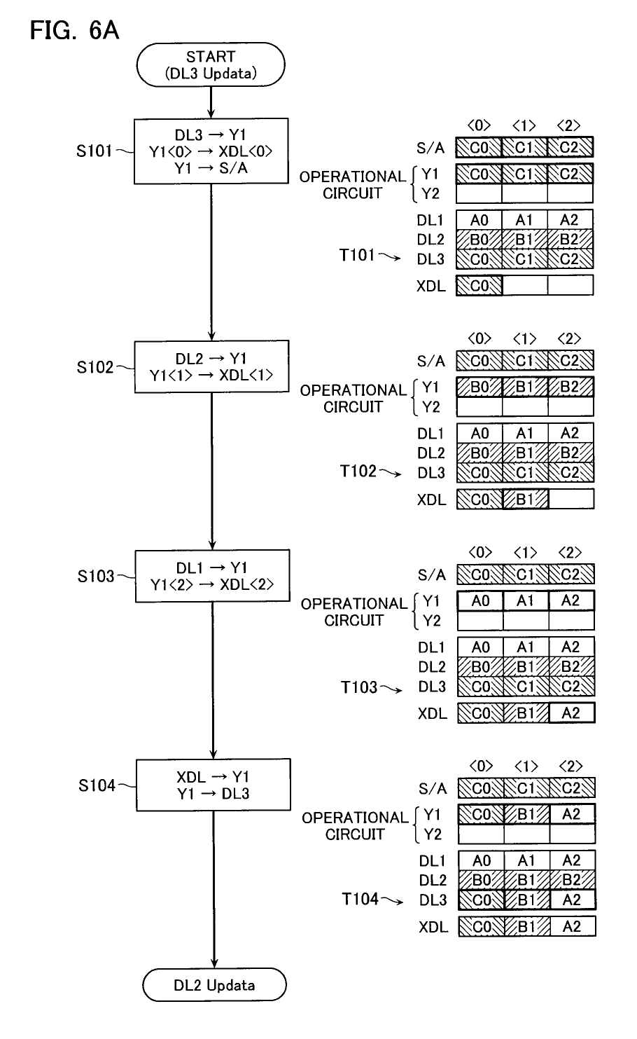

Next, how to convert the logical pages illustrated in the upper portion of FIG. 5 into the physical pages illustrated in the lower portion of FIG. 5 in the sense amplifier and data latch unit 102a will be described with reference to flowcharts of FIGS. 6A to 6C. Replacement of columns <3> to <5>, columns <6> to <8>, and columns <9> to <11> is similar to the replacement of the columns <0> to <2>. Therefore, only the columns <0> to <2> will now be described. Further, the description of three logical pages will be made on the assumption that data of each logical page are retained, in advance, in the data latches DL1, DL2, and DL3, respectively. Moreover, the right side of each of steps of FIGS. 6A to 6C illustrates unit data retained or stored in the sense amplifiers S/A, registers Y1 and Y2 of the operational circuits, and the data latches DL1, DL2, DL3, and XDL after each step is processed. Unit data surrounded by thick frames represent unit data updated in each step.

First, in step S101, the unit data C0, C1, and C2 retained in the data latches DL3 of the columns <0>, <1>, and <2> are copied into the registers Y1 of the same columns <0>, <1>, and <2>, respectively. Then, the unit data C0 stored in the register Y1 of the column <0> is copied into the data latch XDL of the same column <0>. Next, the unit data C0, C1, and C2 stored in the registers Y1 of the columns <0>, <1>, and <2> are copied again into the sense amplifiers S/A of the same columns <0>, <1>, and <2>. After step S101 is processed, the states of the sense amplifiers S/A and others are as illustrated by a reference symbol T101 of FIG. 6A.

Subsequently, in step S102, the unit data B0, B1, and B2 retained in the data latches DL2 of the columns <0>, <1>, and <2> are copied into the registers Y1 of the same columns <0>, <1>, and <2>, respectively. Then, the unit data B1 stored in the register Y1 of the column <1> is copied into the data latch XDL of the same column <1>. After step S102 is processed, the states of the sense amplifiers S/A and others are as illustrated by a reference symbol T102 of FIG. 6A.

Next, in step S103, the unit data A0, A1, and A2 retained in the data latches DL1 of the columns <0>, <1>, and <2> are copied into the registers Y1 of the same columns <0>, <1>, and <2>, respectively. Then, the unit data A2 stored in the register Y1 of the column <2> is copied into the data latch XDL of the same column <2>. After step S103 is processed, the states of the sense amplifiers S/A and others are as illustrated by a reference symbol T103 of FIG. 6A.

Subsequently, in step S104, the unit data C0, B1, and A2 retained in the data latches XDL of the columns <0>, <1>, and <2> are copied into the registers Y1 of the same columns <0>, <1>, and <2>, respectively. Then, the unit data C0, B1, and A2 stored in the registers Y1 of the columns <0>, <1>, and <2> are copied into the data latches DL3 of the same columns <0>, <1>, and <2>, respectively. After step S104 is processed, the states of the sense amplifiers S/A and others are as illustrated by a reference symbol T104 of FIG. 6A.

According to steps S101 to S104, in the data latches DL3 of the respective columns, the unit data which should be written in respective columns of the U page are prepared.

Subsequently, in step S105, the unit data B0, B1, and B2 retained in the data latches DL2 of the columns <0>, <1>, and <2> are copied into the registers Y1 of the same columns <0>, <1>, and <2>, respectively. Then, the unit data BO stored in the register Y1 of the column <0> is copied into the data latch XDL of the same column <0>. After step S105 is processed, the states of the sense amplifier S/A and others are as illustrated by a reference symbol T105 of FIG. 6B.

Next, in step S106, the unit data A0, A1, and A2 retained in the data latches DL1 of the columns <0>, <1>, and <2> are copied into the registers Y2 of the same columns <0>, <1>, and <2>, respectively. Then, the unit data Al stored in the register Y2 of the column <1> is copied into the data latch XDL of the same column <1>. After step S106 is processed, the states of the sense amplifier S/A and others are as illustrated by a reference symbol T106 of FIG. 6B.

Subsequently, in step S107, the unit data C0, C1, and C2 retained in the sense amplifiers S/A of the columns <0>, <1>, and <2> are copied into the registers Y2 of the same columns <0>, <1>, and <2>, respectively. Then, the unit data C2 stored in the register Y2 of the column <2> is copied into the data latch XDL of the same column <2>. After step S107 is processed, the states of the sense amplifiers S/A and others are as illustrated by a reference symbol T107 of FIG. 6B.

Next, in step S108, the unit data B0, A1, and C2 retained in the data latches XDL of the columns <0>, <1>, and <2> are copied into the registers Y2 of the same columns <0>, <1>, and <2>, respectively. Then, the unit data B0, Al, and C2 stored in the registers Y2 of the columns <0>, <1>, and <2> are copied into the data latches DL2 of the same columns <0>, <1>, and <2>, respectively. After step S108 is processed, the states of the sense amplifiers S/A and others are as illustrated by a reference symbol T108 of FIG. 6B.

According to steps S105 to S108, in the data latches DL2 of the respective columns, the unit data which should be written in respective columns of the M page are prepared.

Subsequently, in step S109, the unit data C0, C1, and C2 retained in the sense amplifiers S/A of the columns <0>, <1>, and <2> are copied into the registers Y2 of the same columns <0>, <1>, and <2>, respectively.

Then, the unit data C0, C1, and C2 stored in the registers Y2 of the columns <0>, <1>, and <2> are copied into the data latches XDL of the same columns <0>, <1>, and <2>, respectively. After step S109 is processed, the states of the sense amplifiers S/A and others are as illustrated by a reference symbol T109 of FIG. 6C.

Next, in step S110, the unit data B2 retained in the register Y1 of the column <2> is copied into the data latch XDL of the same column <2>. After step S110 is processed, the states of the sense amplifiers S/A and others are as illustrated by a reference symbol T110 of FIG. 6C.

Subsequently, in step S111, the unit data A0, A1, and A2 retained in the data latches DL1 of the columns <0>, <1>, and <2> are copied into the registers Y2 of the same columns <0>, <1>, and <2>, respectively. Then, the unit data A0 stored in the register Y2 of the column <0> is copied into the data latch XDL of the same column <0>. After step S111 is processed, the states of the sense amplifiers S/A and others are as illustrated by a reference symbol T111 of FIG. 6C.

Next, in step S112, the unit data A0, C1, and B2 retained in the data latches XDL of the columns <0>, <1>, and <2> are copied into the registers Y2 of the same columns <0>, <1>, and <2>, respectively. Then, the unit data A0, C1, and B2 stored in the registers Y2 of the columns <0>, <1>, and <2> are copied into the data latches DL1 of the same columns <0>, <1>, and <2>, respectively. After step S112 is processed, the states of the sense amplifiers S/A and others are as illustrated by a reference symbol T112 of FIG. 6C.

According to steps S109 to S112, in the data latches DL1 of respective columns, the unit data which should be written in respective columns of the L page are prepared.

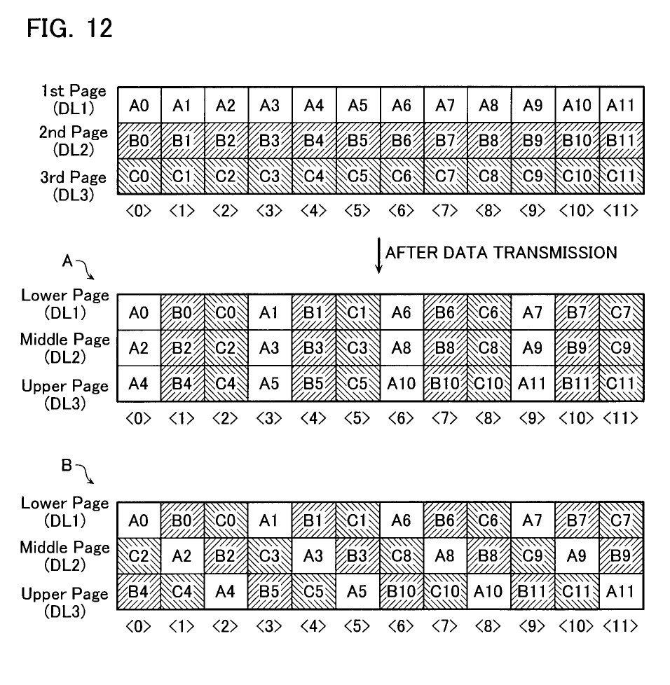

Next, effects according to the replacement will be described with reference to two comparative examples illustrated by reference symbols A and B in FIG. 12.

In the comparative examples illustrated by the reference symbols A and B in FIG. 12, similarly to this embodiment, the first page, the second page, and the third page are distributed to and stored in the L page, the M page, and the U page, respectively. However, in the case of the comparative examples, replacement of unit data between different columns is performed, unlike the case of this embodiment.

Specifically, unit data B0 of the second page retained in the data latch DL2 of the column <0> before data transmission is transmitted to the data latch DL1 of the different column <1>. Similarly, unit data C0 retained in the data latch DL3 of the column <0> before data transmission is transmitted to the data latch DL1 of the different column <2>. Here, it is assumed that a problem occurs in, for example, the sense amplifier S/A of the column <0>. In this case, in the comparative example illustrated by the reference symbol A in FIG. 12, errors occur not only in three unit data A0, B0, and C0 retained in the data latches DL1, DL2, and DL3 of the column <0> but also in unit data A2 and A4 transmitted to the data latches DL2 and DL3 of the column <0> through the sense amplifier S/A of the column <0>. Similarly, in the comparative example illustrated by the reference symbol B in FIG. 12, errors occur also in unit data C2 and B4 transmitted to the data latches DL2 and DL3 of the column <0> through the sense amplifier S/A of the column <0> during the replacement.

As described above, according to the comparative examples illustrated in FIG. 12, in the case where a specific column has a defect, during transmission of unit data, unit data of other columns are also influenced. In this respect, according to this embodiment, replacement of unit data is performed only in the same column, and it is thus possible to prevent a defect of a specific column from influencing other columns.

Further, in the case where replacement of unit data is performed between different columns as in the comparative examples illustrated in FIG. 12, wiring lines corresponding thereto are necessary. As a result, a chip area of the semiconductor memory device increases. In this respect, according to this embodiment, since it is not necessary to install new wiring lines, the chip area does not increase.

As described above, according to this embodiment, it is possible to provide the semiconductor memory device in which the influence of a column defect is small, an increase in the chip area is prevented, and the rates of error occurrence of the logical pages are averaged.

Further, although the semiconductor memory device in which each memory cell stores 3 bits has been described as an example in this embodiment, this embodiment is applicable to any nonvolatile semiconductor memory device in which each memory cell stores two or more bits.

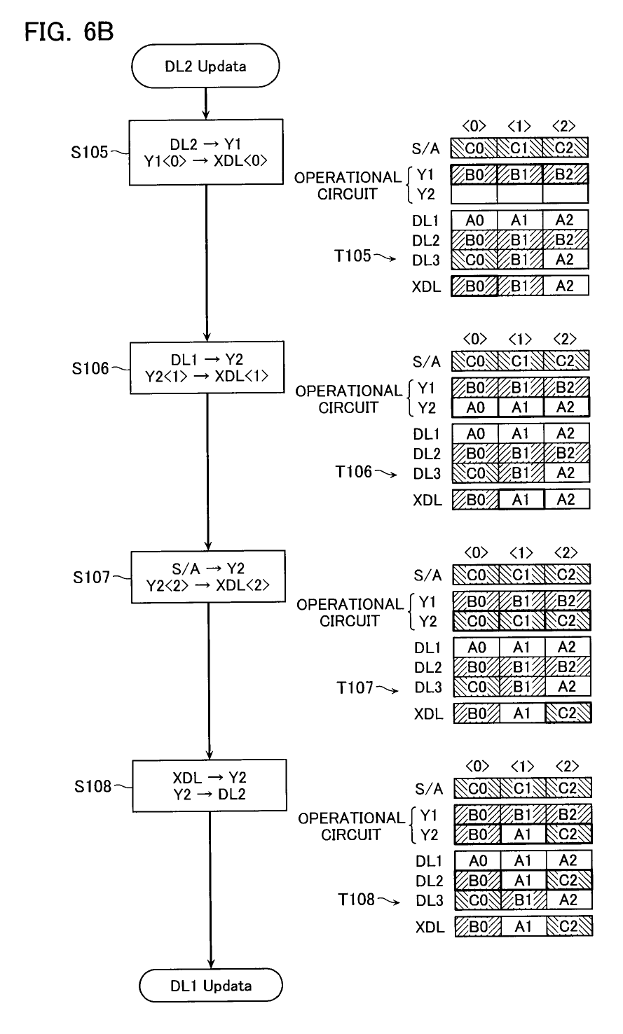

FIGS. 7, 8, and 9 are diagrams illustrating patterns of unit data retained in data latches before and after data replacement (transmission) in the cases where each memory cell stores 2 bits, 3 bits, and 4 bits, respectively.

In the case of a nonvolatile semiconductor memory device in which each memory cell stores 2 bits, as illustrated in FIG. 7, there exists not only a pattern (0) before data transmission but also a data pattern (1) generated by replacing unit data An retained in the data latch DL1 and unit data Bn retained in the data latch DL2 with each other. For example, the pattern (0) and the pattern (1) are alternately repeated for each column, whereby unit data of two logical pages are evenly distributed to two physical pages of an L page and a U page.

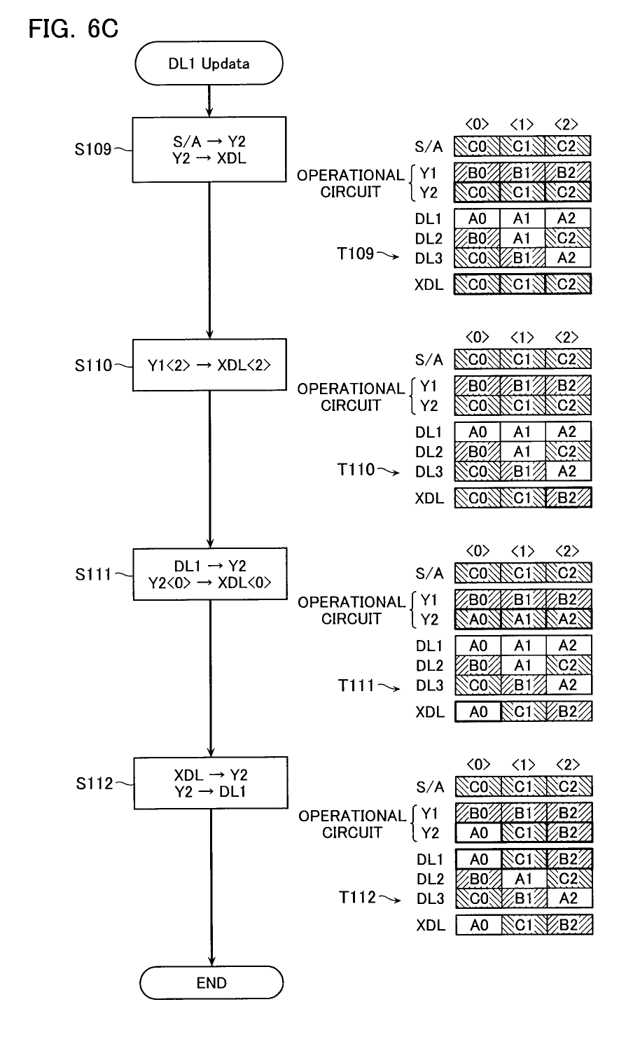

In the case of a nonvolatile semiconductor memory device in which each memory cell stores 3 bits, as illustrated in FIG. 8, not only a pattern (0) before data transmission but also five patterns (1) to (5) exist. Among them, three patterns may be combined and repeated with a period of three columns, thereby capable of averaging the rates of error occurrence of three logical pages. In the case illustrated in FIG. 5, the column <0> corresponds to the pattern (0), the column <1> corresponds to the pattern (4), and the column <2> corresponds to the pattern (5). Then, the pattern (0), the pattern (4), and the pattern (5) are repeated with a period of three columns. Alternatively, all the patterns (0) to (5) including the pattern (0) may be repeated with a period of six columns. In this case, the L page, the M page, and the U page of the six columns include unit data of two first pages, two second pages, and two third pages, respectively, and thus it is possible to average three logical pages.

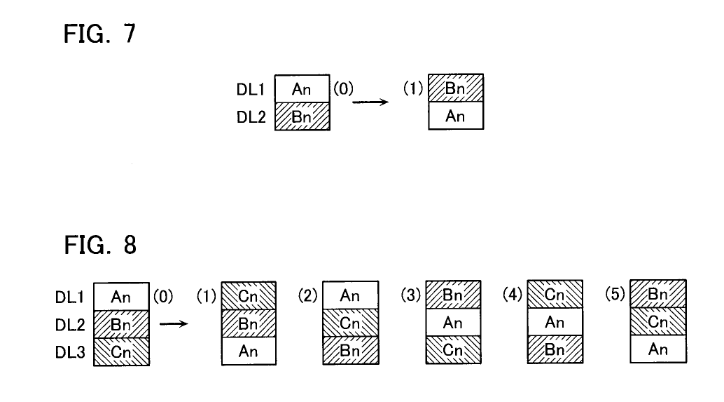

In the case of a nonvolatile semiconductor memory device in which each memory cell stores 4 bits, as illustrated in FIG. 9, not only a pattern (0) before data transmission but also patterns (1) to (23) exist. In this case, for example, four patterns of the patterns (0) to (23) may be repeated with a period of four columns and thus it is possible to average the four logical pages.

Moreover, the replacement of data in the embodiment described above is effective particularly when an increase in the rate of error occurrence results from an increase in the number of write times. For this reason, the replacement of data may not be performed early, and after the number of write times exceeds a predetermined value, data transmission may be performed.

### Second Embodiment

In the first embodiment, as illustrated in FIGS. 6A to 6C, transmission of data of every column between the data latches, the sense amplifier, and the registers of the operational circuit is repeated, thereby generating data to be written in the physical pages.

In contrast, in a semiconductor memory device according to a second embodiment, replacement of unit data is performed at intervals of every predetermined number of columns.

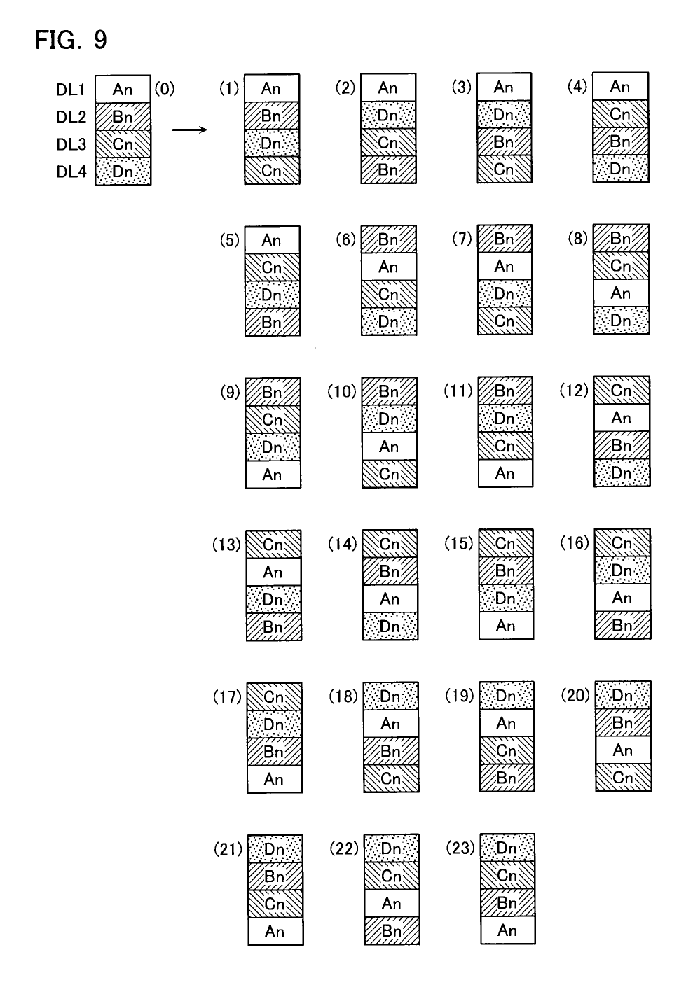

A specific example of this embodiment is illustrated in FIG. 10. In the case of the specific example, as illustrated by thick frames in the lower portion of FIG. 10, unit data replacement is performed only for every other column, that is, the columns <0>, <2>, <4>, <6>, <8>, and <10>. In other words, for the other columns <1>, <3>, <5>, <7>, <9>, and <11>, unit data are transmitted to the physical pages as they are. Further, in the case illustrated in FIG. 10, the columns <0>, <2>, <4>, <6>, <8>, and <10> correspond to the patterns (3), (4), (5), (1), (2), and (4) illustrated in FIG. 8, respectively.

According to this embodiment, since unit data of every column is not transmitted, there is a limit in averaging the rates of error occurrence of the logical pages as compared to the first embodiment. However, since it is possible to reduce the power consumption during unit data replacement as compared to the first embodiment, this embodiment is effective when a variation in the rates of error occurrence of the physical pages is not large.

### Third Embodiment

A third embodiment is an example in which only unit data of specific columns are replaced.

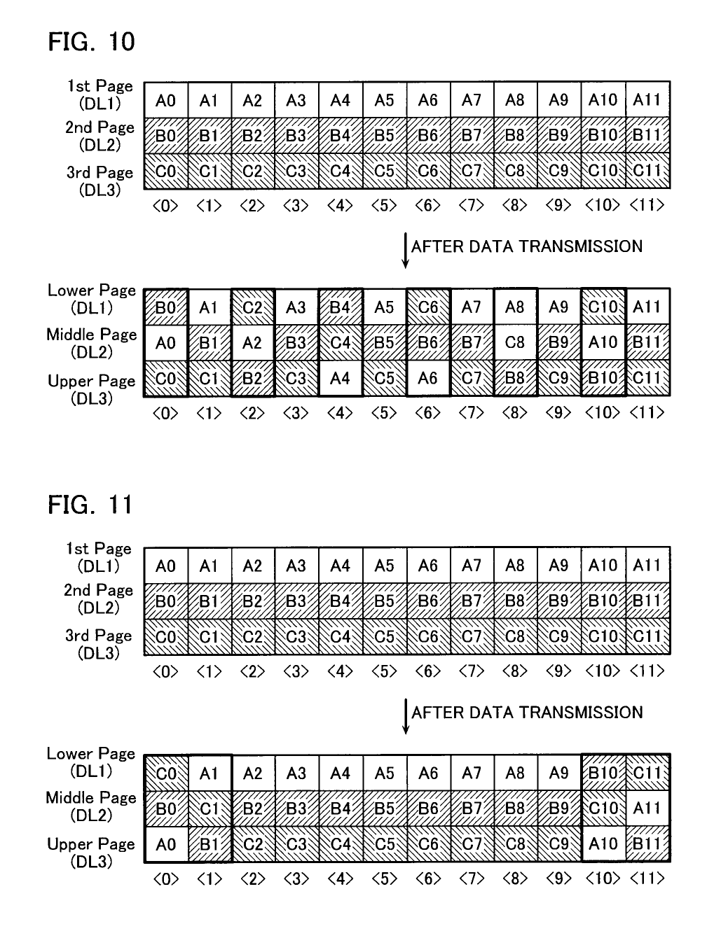

A specific example of this embodiment is illustrated in FIG. 11. In the case illustrated in FIG. 11, among columns <0> to <11> constituting one page, unit data of the columns <0>, <1>, <10>, and <11> in the vicinities of both ends in which error easily occurs generally due to the configuration of the memory cell array are replaced as the patterns (1), (2), (5), and (4) illustrated in FIG. 8.

In this way, columns on which unit data replacement is performed are limited. Therefore, it is possible to suppress the power consumption during the data replacement, as compared to the first embodiment. Further, since the columns on which data replacement is not performed originally make a minor contribution to averaging of the rates of error occurrence of the logical pages, in the effect of averaging the rates of error occurrence of the logical pages, this embodiment is comparable to the first embodiment.

Moreover, in the example illustrated in FIG. 11, the columns on which unit data replacement is performed are determined based on the assumption that the rate of error occurrence is high in columns in the vicinities of both ends of each of the physical pages. However, the columns on which unit data replacement is performed may be determined based on the rates of error occurrence obtained in advance by a test, or the like.

[Others]

While certain embodiments have been described, these embodiments have been presented by way of example only, and are not intended to limit the scope of the inventions. Indeed, the novel methods and systems described herein may be embodied in a variety of other forms: furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device, comprising:
a memory cell array including a plurality of word lines, a plurality of bit lines intersecting with the plurality of word lines, and a plurality of memory cells selected by the word lines and the bit lines, each memory cell being capable of storing N-bit (N is an integer of 2 or more) data, a set of n-th bits (n is an integer of 1 to N) of a plurality of memory cells selected by one of the word lines constituting an n-th physical page, and a predetermined number of the bit lines constituting one column; and
a data writing unit that divides each of first to N-th input data of the length of the physical page or less input from the outside into unit data of the length of the column, changes at least a portion of the order of unit data of the first to N-th input data of a predetermined column in the predetermined column before data writing, and performs writing.

2. The nonvolatile semiconductor memory device according to claim 1,
wherein the data writing unit includes first to N-th data retaining units for each column,
divides each of the first to n-th input data into the unit data of the length of the column, retains a plurality of unit data of the n-th input data in the N-th data retaining units of the plurality of columns,
transmits unit data of each of the first to N-th data retaining units of the predetermined column to another of the first to N-th data retaining units of the same column before data writing, and then writes the unit data of the first to N-th data retaining units of the plurality of columns as data to first to N-th physical pages of the same columns, respectively.

3. The nonvolatile semiconductor memory device according to claim 2,
wherein the data writing unit transmits the unit data of each of the first to N-th data retaining units to another of the first to N-th data retaining units of the same column at intervals of a predetermined number of columns.

4. The nonvolatile semiconductor memory device according to claim 2,
wherein the data writing unit transmits the unit data of each of the first to N-th data retaining units to another of the first to N-th data retaining units of the same column for only a predetermined number of columns, in which rates of error occurrence during data reading are higher, of the plurality of columns.

5. The nonvolatile semiconductor memory device according to claim 4,
wherein the predetermined number of columns on which unit data transmission is performed are a predetermined number of columns close to both ends of the physical page.

6. The nonvolatile semiconductor memory device according to claim 2,
wherein the data writing unit includes an (N+1)-th data retaining unit for each column and, before data writing, temporarily stores the unit data of each of the first to N-th data retaining units of a predetermined column in the (N+1)-th data retaining unit when transmitting the unit data of each of the first to N-th data retaining units to another of the first to N-th data retaining units of the same column.

7. The nonvolatile semiconductor memory device according to claim 2,
wherein the data writing unit includes an operational unit for each column, which performs an operation necessary when transmitting the unit data of each of the first to N-th data retaining units of the corresponding column to another of the first to N-th data retaining units of the same column.

8. A nonvolatile semiconductor memory device, comprising:
a memory cell array including a plurality of word lines, a plurality of bit lines intersecting with the plurality of word lines, and a plurality of memory cells selected by the word lines and the bit lines, each memory cell being capable of storing N-bit (N is an integer of 2 or more) data, a set of n-th bits (n is an integer of 1 to N) of a plurality of memory cells selected by one of the word lines constituting an n-th physical page, and a predetermined number of the bit lines constituting one column; and
a data writing unit that divides each of first to N-th input data of the length of the physical page or less input from the outside into unit data of the length of the column, changes at least a portion of the order of unit data of the first to N-th input data of a predetermined column in the predetermined column before data writing, and performs writing,
the first to N-th input data being all or a portion of first to N-th ECC frames which include information data and redundant data used for error correction on the information data.

9. The nonvolatile semiconductor memory device according to claim 8,
wherein the data writing unit includes first to N-th data retaining units for each column,
divides each of the first to n-th input data into the unit data of the length of the column, retains a plurality of unit data of the N-th input data in the N-th data retaining units of the plurality of columns,
transmits unit data of each of the first to n-th data retaining units of the predetermined column to another of the first to N-th data retaining units of the same column before data writing, and then writes the unit data of the first to N-th data retaining units of the plurality of columns as data to first to N-th physical pages of the same columns, respectively.

10. The nonvolatile semiconductor memory device according to claim 9,
wherein the data writing unit transmits the unit data of each of the first to N-th data retaining units to another of the first to N-th data retaining units of the same column at intervals of a predetermined number of columns.

11. The nonvolatile semiconductor memory device according to claim 9,
wherein the data writing unit transmits the unit data of each of the first to N-th data retaining units to another of the first to N-th data retaining units of the same column for only a predetermined number of columns, in which rates of error occurrence during data reading are higher, of the plurality of columns.

12. The nonvolatile semiconductor memory device according to claim 11,
wherein the predetermined number of columns on which unit data transmission is performed are a predetermined number of columns close to both ends of the physical page.

13. The nonvolatile semiconductor memory device according to claim 9,
wherein the data writing unit includes an (N+1)-th data retaining unit for each column and, before data writing, temporarily stores the unit data of each of the first to N-th data retaining units of a predetermined column in the (N+1)-th data retaining unit when transmitting the unit data of each of the first to N-th data retaining units to another of the first to N-th data retaining units of the same column.

14. The nonvolatile semiconductor memory device according to claim 9,
wherein the data writing unit includes an operational unit for each column, which performs an operation necessary when transmitting the unit data of each of the first to N-th data retaining units of the corresponding column to another of the first to N-th data retaining units of the same column.

15. A nonvolatile semiconductor memory device, comprising:
a memory cell array including a plurality of word lines, a plurality of bit lines intersecting with the plurality of word lines, and a plurality of memory cells selected by the word lines and the bit lines, each memory cell being capable of storing N-bit (N is an integer of 2 or more) data, a set of n-th bits (n is an integer of 1 to N) of a plurality of memory cells selected by one of the word lines constituting an n-th physical page, and a predetermined number of the bit lines constituting one column; and
a data writing unit that writes first to N-th input data of the length of the physical page or less input from the outside into the first to N-th physical pages,
the n-th physical page of the memory cell array storing data which becomes the n-th input data when data of a predetermined column is replaced with data of the same column of another physical page.

16. The nonvolatile semiconductor memory device according to claim 15,
wherein the data writing unit includes first to N-th data retaining units for each column,
divides each of the first to N-th input data into the unit data of the length of the column, retains a plurality of unit data of the n-th input data in the n-th data retaining units of the plurality of columns,
transmits unit data of each of the first to N-th data retaining units of the predetermined column to another of the first to N-th data retaining units of the same column before data writing, and then writes the unit data of the first to N-th data retaining units of the plurality of columns as data to first to N-th physical pages of the same columns, respectively.

17. The nonvolatile semiconductor memory device according to claim 15,
wherein the n-th physical page of the memory cell array stores data which becomes the n-th input data when data of each column is replaced with data of the same column of another physical page at intervals of a predetermined number of columns of the plurality of columns.

18. The nonvolatile semiconductor memory device according to claim 15,
wherein the n-th physical page of the memory cell array stores data which becomes the n-th input data when data of each of a predetermined number of columns, in which rates of error occurrence during data reading are higher, of the plurality of columns is replaced with data of the same column of another physical page.

19. The nonvolatile semiconductor memory device according to claim 18,
wherein the predetermined number of columns in which the rates of error occurrence are higher during the data reading are the predetermined number of columns close to both ends of the physical page.

20. The nonvolatile semiconductor memory device according to claim 16,
wherein the data writing unit includes an (N+1)-th data retaining unit for each column, and temporarily stores the unit data of each of the first to N-th data retaining units of a predetermined column in the (N+1)-th data retaining unit when transmitting the unit data of each of the first to N-th data retaining units to another of the first to N-th data retaining units of the same column.
